(19) United States
(12) Patent Application Publication
(10) Pub. No.: US 2025/0224525 A1
(43) Pub. Date: Jul. 10, 2025

(54) SCINTILLATOR, RADIATION DETECTOR, RADIATION IMAGING SYSTEM, AND METHOD OF MANUFACTURING SCINTILLATOR

(71) Applicant: CANON KABUSHIKI KAISHA, Tokyo (JP)

(72) Inventors: TAMAKI KOBAYASHI, Kanagawa (JP); TOMOYUKI OIKE, Kanagawa (JP); MASAMI TSUKAMOTO, Kanagawa (JP); YOSHITO SASAKI, Tokyo (JP); DAIKI NAKAGAWA, Kanagawa (JP)

(21) Appl. No.: 19/012,279

(22) Filed: Jan. 7, 2025

(30) Foreign Application Priority Data
Jan. 9, 2024 (JP) 2024-001500

(51) Int. Cl. G01T 1/20; G01T 1/202; H10F 39/18

(52) U.S. Cl. CPC G01T 1/20188; G01T 1/2023; H10F 39/1898

(57) ABSTRACT

A scintillator comprises a plurality of columnar crystals arranged on a substrate and each configured to convert radiation into light, and protection films configured to cover surfaces of the plurality of columnar crystals. The plurality of columnar crystals contain an activator agent, and the protection films contain silica. After the scintillator is irradiated with radiation of 1,000 Gray (Gy), a quantity of light emission lowers by not more than 35%, as compared with a quantity of light emission before radiation irradiation.

### BACKGROUND

### Technical Field

One disclosed aspect of the embodiments relates to a scintillator, a radiation detector, a radiation imaging system, and a method of manufacturing the scintillator.

### Description of the Related Art

Some flat panel detectors (FPDs) used for X-ray imaging in the medical site receive, by a radiation detection scintillator, X-rays having passed through a subject and detect, by a light-receiving element, light emitted by the scintillator. As the scintillator, for example, a structure obtained by forming a columnar crystal group of an alkali metal halide such as cesium iodide formed on a substrate is used. In the columnar crystal group, a gap is formed between the columnar crystals. Light is repeatedly, totally reflected in the columnar crystal containing a high refractive index cesium iodide by a ratio between the refractive index (about 1.8) of cesium iodide and the refractive index (1.0) of air, and can effectively be guided to the light-receiving element.

However, since cesium iodide alone has a small quantity of light emission, an element generally called an activator agent, for example, thallium that can replace part of cesium as a cation may be added. The activator agent can be introduced into a crystal by depositing (codepositing) a raw material containing thallium such as thallium iodide at the time of deposition of an alkali metal halide. On the other hand, it is known that when irradiation with radiation is performed for a long period of time, the scintillator is colored to lower the quantity of light emission, that is, luminance. Such coloring is called color center formation. Japanese Patent Laid-Open No. 2017-161408 discloses a technique of suppressing color center formation by lowering the concentration of an activator agent.

### SUMMARY

One disclosed embodiment has been made in consideration of the above-described disadvantage, and can provide a radiation detection scintillator that can suppress lowering in luminance caused by radiation irradiation for a long period of time while suppressing burn-in on the scintillator.

According to one aspect of the disclosure, there is provided a scintillator comprises a plurality of columnar crystals arranged on a substrate and each configured to convert radiation into light, and protection films configured to cover surfaces of the plurality of columnar crystals. The plurality of columnar crystals contain an activator agent, and the protection films contain silica. After the scintillator is irradiated with radiation of 1,000 Gray (Gy), a quantity of light emission lowers by not more than 35%, as compared with a quantity of light emission before radiation irradiation.

Further features of the present disclosure will become apparent from the following description of exemplary embodiments with reference to the attached drawings.

### BRIEF DESCRIPTION OF THE DRAWINGS

FIG. 1 is a graph showing the relationship between a cumulative irradiation dose of radiation and a lowering rate of a quantity of light emission according to Example 1 of an embodiment and Comparative Example 1;

FIG. 2 is a sectional view showing a state in which a columnar crystal group is covered with protection films according to the embodiment;

FIG. 3 is a sectional view showing a state in which a columnar crystal group is covered with protection films according to the embodiment;

FIG. 4A is a view showing a radiation detector according to the embodiment;

FIG. 4B is a view showing a radiation detector according to the embodiment;

FIG. 5 is a graph showing the relationship between a wavelength and a reflectance before radiation irradiation according to Example 5 of the embodiment and Comparative Example 3;

FIG. 6 is a graph showing the relationship between a wavelength and a reflectance after irradiation with radiation of 1,000 Gy according to Example 5 of the embodiment and Comparative Example 3; and

FIG. 7 is a view for explaining an example of the configuration of a radiation imaging system.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but all such features are not required, and multiple such features may be combined as appropriate. Furthermore, in the attached drawings, the same reference numerals are given to the same or similar configurations, and redundant description thereof is omitted.

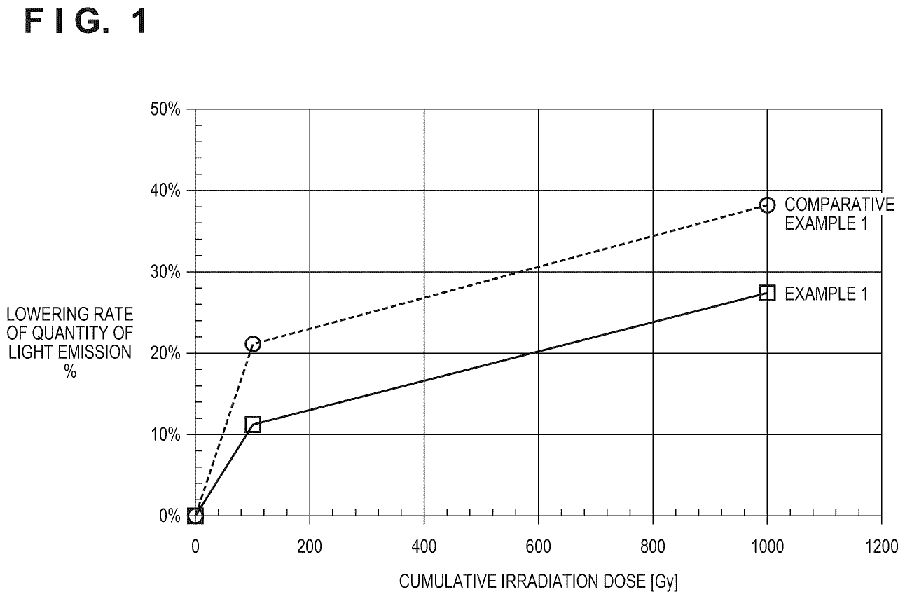

FIG. 1 is a graph for comparing the quantity of light emission of a scintillator of Example 1 to which a configuration according to this embodiment (to be described later) is applied with the quantity of light mission of a scintillator of Comparative Example 1 to which the configuration according to this embodiment is not applied. Lowering of the quantity of light emission can be obtained as a lowering rate given by equation (1) below. The quantity of light emission before radiation irradiation in this graph corresponds to a state before irradiation with radiation for durability evaluation of the scintillator, and the quantity of light emission after irradiation with radiation corresponds to a state after irradiation with radiation for durability evaluation. The lowering rate of the quantity of light emission is given by:

$$lowering rate of quantity of light emission = 1 - ( quantity of light emission after radiation irradiation / quantity of light emission before radiation irradiation ) \qquad ( 1 )$$

In this example, a radiation irradiation condition for durability evaluation is that a tube voltage is 130 kV, an aluminum added filter has a thickness of 1 mm, and an irradiation dose rate is 0.1 Gy (gray)/min. Furthermore, the measurement condition of the quantity of light emission complies with radiation quality RQA5 of the international standards. In FIG. 1, the lowering rate of the quantity of light emission is plotted when the cumulative irradiation dose reaches 100 Gy and 1,000 Gy. In the graph, the measurement points are connected by a straight line, but it is considered that lowering of the quantity of light emission is actually represented by a smooth curve. It is known that in Example 1, the lowering rate of the quantity of light emission is reduced to about half after irradiation of 100 Gy, as compared with Comparative Example 1. In Example 1, even after irradiation of 1,000 Gy, the lowering rate of the quantity of light emission is low, as compared with Comparative Example 1. According to this embodiment, lowering of the quantity of light emission of a scintillator can be reduced with respect to the cumulative irradiation dose of radiation. The scintillator according to this embodiment will be described in detail below.

### (Scintillator)

As the base material of the scintillator used in this embodiment, an alkali metal halide compound such as cesium iodide that can form a columnar crystal group can be selected. To add a sufficient light emission function to the base material, for example, thallium (Tl) can be used as an activator agent. If the concentration of thallium used as an activator agent is low, a kind of burn-in phenomenon called bright burn may occur in the scintillator. To suppress bright burn, it is known that the concentration of the activator agent is increased. In consideration of reduction of bright burn, the concentration of thallium as the activator agent is preferably set to 0.25 mol % or more. The scintillator according to this embodiment can be manufactured by, for example, a general vacuum film forming means such as a vapor deposition method.

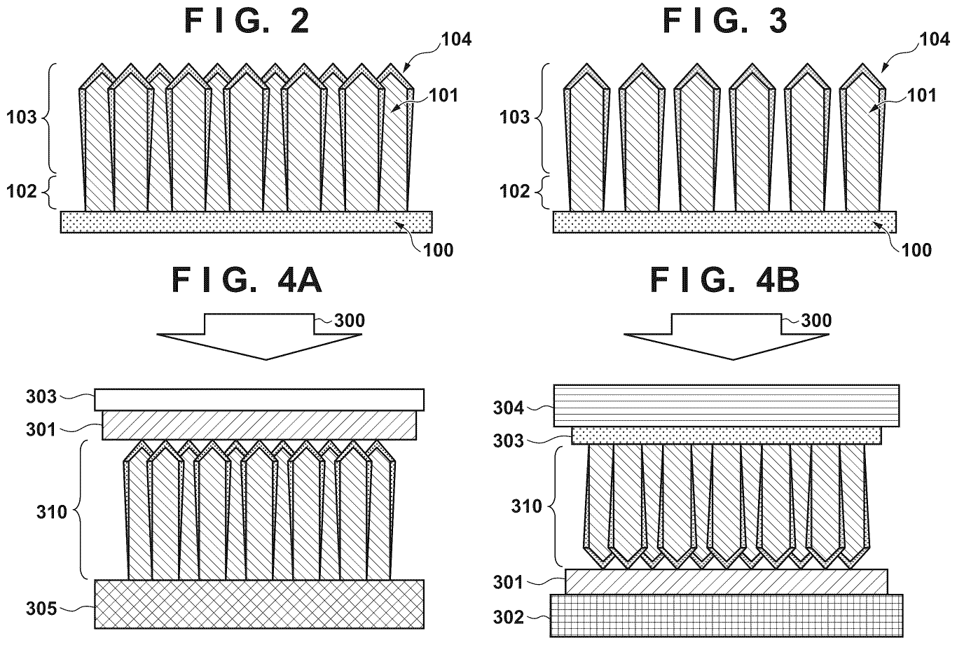

According to one aspect of this embodiment, as shown in FIGS. 2 and 3, the entire crystal separation region of a scintillator formed from an aggregate of columnar crystals formed on a substrate is continuously covered with protection films (to be described later) and the initial layer of the scintillator is partially covered with the protection films.

The initial layer of the scintillator is, for example, a minute crystal nucleus layer formed on the substrate in an early stage of deposition by selecting a substrate temperature, pressure, and deposition rate in a vapor deposition step of a columnar crystal using cesium iodide as the base material. The initial layer indicates a region where a crystal nucleus preferentially grows in the orientation in an early stage of deposition to have a film thickness (height of columnar crystals) of 10 μm to several tens of μm. In this region, the orientation and size of the columnar crystal are not completely determined.

The crystal separation region of the scintillator indicates a region where deposition further progresses from the initial layer, the crystal orientation of the columnar crystal is determined as the orientation, and the columnar crystal grows to a larger size to have a film thickness of several tens of μm or more. In this region, the sizes of the columnar crystals increase, the columnar crystals are separated from each other, and gaps are formed and maintained between the crystals. If a liquid material is used to form protection films, the liquid material seeps into the gaps in the crystal separation region by a capillary phenomenon, thereby making it possible to form continuous protection films.

When a liquid material for forming protection films partially seeps into gaps in the region where the outer shape of each columnar crystal in the initial layer is unclear, discontinuous protection films can be formed. If many of the gaps in the initial layer are filled with the protection films, light emitted by the scintillator and guided may scatter and spread, thereby lowering the spatial resolution. When the protection films in the crystal separation region are continuously formed and the protection films in the initial layer are discontinuously formed, it can be possible to obtain the moisture resistance and spatial resolution of the scintillator.

### (Protection Film)

The liquid material of the protection films used in this embodiment can contain, as a component, for example, a polysilazane-based inorganic polymer such as perhydro-polysilazane that is a silica conversion material containing silicon, nitrogen, and hydrogen. The concentration of the liquid material of the protection films can be adjusted by an organic solvent. The liquid material can be manufactured by appropriately using a liquid added with various catalysts. Depending on the kind of raw material selected, heating may appropriately be performed at the time of hydrolysis reaction or conversion reaction into silica glass. More simply, such raw material that the above reaction occurs at room temperature may be selected. If the concentration of the silica conversion material in the liquid material of the protection films is lower than 0.5 weight percent (wt %), the continuity of the formed protection films is insufficient, and thus the moisture resistance is insufficient. If the concentration of the silica conversion material in the liquid material of the protection films is higher than 2 wt %, the gaps between the columnar crystals are filled with the formed protection films, or drying of an organic solvent and silica conversion progress outside the columnar crystal group of the scintillator before soaking of the liquid material in the scintillator progresses. Therefore, this is inappropriate because, for example, a crack occurs when drying the applied protection films or the scintillator is floated or peeled from the substrate. By setting the concentration of the silica conversion material within the range of 0.5 wt % (inclusive) to 2 wt % (inclusive), it is possible to obtain the moisture resistance and spatial resolution of the scintillator.

The protection films applicable to this embodiment can be formed using the capillary phenomenon of the liquid material. The coating range of the protection films gradually changes from a discontinuous coating state to a continuous coating state from the initial layer to the crystal separation region, as shown in FIG. 2. Even if separation between the columnar crystals sufficiently progresses to obtain clear gaps, and the side walls of the columnar crystals are coated with the protection films, the protection films are continuously formed in a region where the gaps between the protection films covering the columnar crystals can be maintained, that is, the crystal separation region. This can improve a moisture-proof property without degrading the spatial resolution of the scintillator.

### (Method of Forming Protection Film)

As a method of forming a protection film, a method using a liquid, such as a spin coating method, a spray coating method, a dip-coating method, a flow coating method, or a bar coating method, is appropriately selected, thereby making it possible to readily obtain coating of a desired thickness on columnar crystals, as compared with, for example, a vapor-phase growth method. By using a liquid material, it becomes easy to supply a large amount of the raw material to, particularly, a concave portion of the surface of the columnar crystal group, and it is thus possible to reduce the surface roughness of surface unevenness of the columnar crystals.

For example, by using the spin coating method, the time during which the applied liquid material remains in the distal end portions of the columnar crystals becomes long by centrifugal force generated by rotation, and it is thus possible to readily form protection films in the distal end portions of the columnar crystals. In addition, it is possible to suppress formation of the protection films between the columnar crystals to the necessary minimum.

Alternatively, by using the spray coating method, it is possible to uniform the application amount of the liquid material to a large-area substrate. By using the dip coating method, it is possible to supply a large amount of the liquid material to both the surfaces of the substrate at once. In addition, in the dip coating method, by holding the distal end portions of the columnar crystals downward in the vertical direction at the time of applying or drying the liquid material, it is possible to suppress formation of the protection films between the columnar crystals. It is also possible to accelerate a chemical reaction by raising the temperature, heating, or humidifying to the extent that the columnar crystals do not deliquesce, as needed, at the time of supplying or applying the liquid material and after the film formation.

If an abnormal crystal growth portion having large unevenness exists at the time of depositing the scintillator, coating treatment is preferably performed for the scintillator by forming a very thin film by a vapor-phase growth method using metal alkoxide or the like before protection film treatment according to this embodiment. After taking a measure that suppresses a degradation in characteristic for a period necessary for a next step or storage by the coating treatment to reduce the scintillator surface roughness (planarization treatment), the protection film formation according to this embodiment may be executed. As a method for the planarization treatment, a method of pressurizing by a flat plate or a roller or a method of removing the abnormal crystal growth portion can be used instead of the coating treatment, and the present embodiment does not limit the method as long as it is possible to reduce scintillator surface roughness.

As a protection film formation sequence, after deposition, very thin protection films may be formed in the coating treatment of the scintillator by metal alkoxide such as ethyl silicate. This can take a measure that suppresses a degradation in characteristic during a time until treatment of a next step is completed or during a storage period, that is, maintain the moisture-proof property. After that, planarization treatment of the abnormal crystal growth portion of the scintillator film may appropriately be performed, and the protection film formation according to this embodiment may further be executed.

If the spray coating method is used for forming the protection films, it is possible to readily form protection films to have a large area according to this embodiment by controlling the application amount to the scintillator surface by a wet film thickness.

The wet film thickness W is a film thickness immediately after application, and is given by:

$$W = \frac{\frac{G \times L / S}{d}}{A} \qquad ( 2 )$$

where G represents a discharge amount per unit time, L represents a total nozzle moving distance, S represents a nozzle scanning speed, d represents the density of the liquid material, and A represents an application area.

For example, when the discharge amount per unit time is 7.2 g/min, the application time is 2 min, the density of the liquid material is 0.8 g/cc, and the application area is a 30-cm square, the wet film thickness is 200 μm. Note that the applied liquid material is immediately soaked in the scintillator, and silica conversion occurs in a process of drying the organic solvent, thereby forming protection films.

### (Thickness of Protection Film)

By performing analysis by Energy Dispersive X-ray fluorescence Spectrometry (EDX), the presence of silicon (Si) is confirmed in the initial layer and the crystal separation region of the scintillator in which the protection films are formed. The amount of Si is greatest at the distal end portions of the column crystals in the crystal separation region, followed by the middle portion, and there is also some in the initial layer. It is considered that the protection film formed on the scintillator can form a regular tetrahedron structure (the Si—O bond length is 0.162 nm, so the height of the regular tetrahedron is 0.216 nm) with four oxygen (O) atoms coordinated to silicon (Si). According to analysis, the number of molecular layers can be estimated to be between 15 and 30 layers due to the repetition of the regular tetrahedral structure. A thickness of several nanometers is obtained, the gaps between the protection films covering the crystals of the scintillator are mostly maintained, and the gaps between the crystals are maintained. In addition, it is considered that the thickness of the protection films has a sufficient moisture-proof property.

### (Coating Range of Protection Films)

The coating range of the protection films in the film thickness direction of the scintillator according to this embodiment will be described below. For example, when columnar crystals are formed on the substrate by a method such as the vapor deposition method, the columnar crystals each of which grows from a crystal nucleus with a micro diameter are gradually selected and fused to form a columnar crystal group, and thus the column diameter of the columnar crystal increases as the film thickness increases. On the other hand, although the gap between the columnar crystals is very small for the small crystal nucleuses, separation between the columns progresses as the film thickness increases, and an substantially constant interval is maintained from a certain film thickness. If the protection films according to this embodiment are formed in a region formed from crystal nucleuses with a micro diameter in the initial stage of vapor deposition, the gaps between the columnar crystals are filled with the protection films, thereby making it possible to reduce the gaps. Therefore, guided light may scatter, thereby lowering the spatial resolution.

### (Thermal Treatment)

In this embodiment, after forming the above-described protection films on the scintillator surface, thermal treatment is performed. Main parameters for the condition of thermal treatment are the temperature and time. Since heating is performed after forming the protection films, it is possible to perform heating in an air atmosphere. Even if thermal treatment is performed in air without controlling an ambient gas, there is no influence of deliquescence on the spatial resolution. Therefore, it is possible to use an inexpensive commercial clean oven, hotplate, electric furnace, or the like.

It is possible to suppress, by thermal treatment of this embodiment, lowering of the quantity of light emission caused by radiation irradiation, and this is considered as follows. By forming the protection films, desorption of a halide element as a constituent element from the scintillator surface is difficult and it is difficult to react with a surface adsorption element. By performing thermal treatment under this situation, a crystal array in the scintillator is homogenized, thereby making it difficult to form a defect. It is supposed that energy of thermal treatment is correlated with homogenization of the crystal array, which influences the lowering rate of the quantity of light emission depending on the condition of thermal treatment.

### (Evaluation)

When evaluating the size and change of the column diameter of the columnar crystal of the manufactured scintillator, the shape can be observed by, for example, a Scanning Electron Microscope (SEM) or the like. In addition, the chemical composition of a deposition film can be evaluated by, for example, fluorescent X-ray analysis or inductively coupled plasma analysis, and the crystallinity can be evaluated by, for example, X-ray diffraction analysis or the like.

The formation state of the protection film can be observed by a Transmission Electron Microscope (TEM) or element mapping evaluation using Energy Dispersive X-ray fluorescence Spectrometry (EDX). The reflectance of the scintillator can be evaluated using a spectrophotometer.

The evaluation of the spatial resolution characteristic can be compared quantitatively by measuring the modulation transfer function (MTF). Detective quantum efficiency (DQE) and the quantity of light emission of the scintillator can be evaluated using various photodetectors such as a light-receiving element and a camera including a Charge-Coupled Device (CCD) and a Complementary Metal Oxide Semiconductor (CMOS).

As an X-ray irradiation apparatus used to evaluate radiation durability, an X-ray generation apparatus that can perform irradiation at an irradiation dose rate of about 0.1 Gy/min can be used.

### (Radiation Detector)

As a radiation detector using the scintillator according to this embodiment, for example, there is provided a configuration obtained by forming a plurality of columnar crystals 310 on a substrate 305 with an optical sensor on which photoelectric conversion elements are arranged and combining them with a reflective layer 303 via an adhesive layer 301, as shown in FIG. 4A. An arrow 300 indicates the direction of irradiation. This configuration is sometimes called a direct type. Alternatively, for example, there is provided a configuration obtained by forming the plurality of columnar crystals 310 on a substrate 304 including the reflective layer 303 and combining them with a substrate 302 with an optical sensor via the adhesive layer 301, as shown in FIG. 4B. This configuration is sometimes called an indirect type. Furthermore, to adjust the spatial resolution and sensitivity, an optical system element or material such as a Fiber Optic Plate (FOP) or light absorption filter may be added between the scintillator and the substrate 302 with the optical sensor on which the photoelectric conversion elements are arranged.

The above-described scintillator and radiation detector can be applied to a radiation detection apparatus for detecting radiation, a radiation imaging apparatus, and a radiation imaging system. As radiation, X-rays are typically used but α-rays, β-rays, or the like may be used.

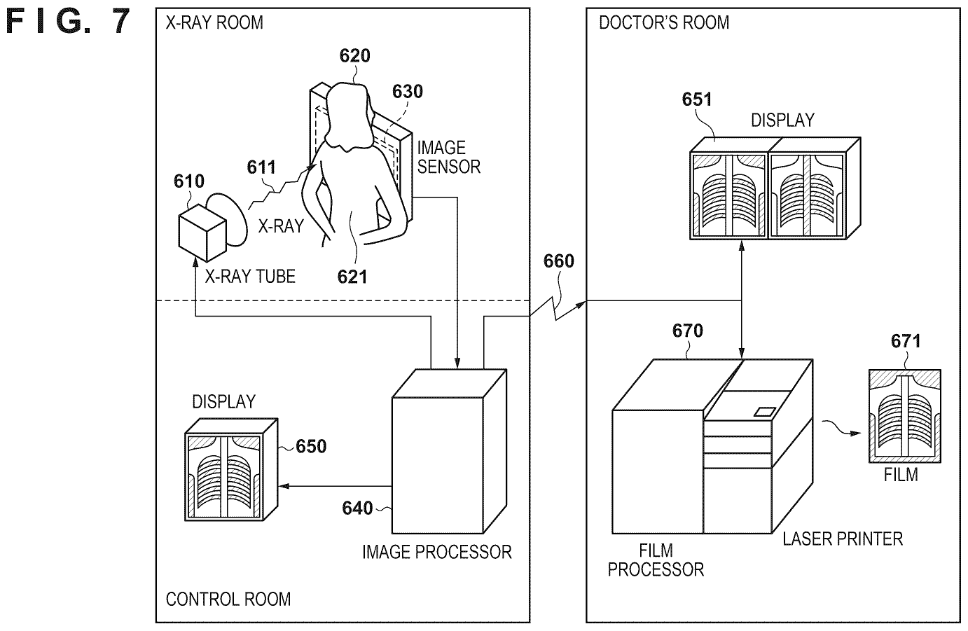

FIG. 7 shows a radiation imaging system as an example of the use form of the radiation detector according to this embodiment. Radiation 611 generated by a radiation source 610 is transmitted through a chest 621 of a subject 620 such as a patient to enter a radiation detection apparatus 630. The radiation 611 entering the apparatus 630 contains information about the inside of the body of the patient 620, and the apparatus 630 acquires electric information corresponding to the radiation 611. This electric information is converted into a digital signal by an image processor 640 including a signal processing unit, and undergoes predetermined signal processing.

The user such as a doctor can observe a radiation image corresponding to the electric information on, for example, a display 650 in a control room. The user can transfer the radiation image or data thereof to a remote place by a predetermined communication apparatus 660, and observe the radiation image on a display 651 in a doctor room at another place. In addition, the user can record the radiation image or data thereof in a predetermined recording medium, and can record it on, for example, a film 671 by a film processor 670.

Some preferred examples have been described above, but the present disclosure is not limited to these, and may partially be modified without departing from the scope of the invention. In addition, individual terms described in this specification are merely used for the purpose of explaining the present disclosure, and the present disclosure is not limited to the strict meanings of the terms and can also incorporate their equivalents.

Examples of the scintillator applied with the configuration according to this embodiment and comparative examples of the scintillator will be described below.

### Example 1

In this example, a scintillator having a columnar crystal structure is formed by vapor deposition. A material supply source filled with cesium iodide as a base material to be deposited, a material supply source filled with thallium iodide as an activator agent to be deposited, and a substrate on which crystals were formed were arranged in a vacuum evaporation apparatus. As the substrate, a glass substrate on which an aluminum reflective layer having a thickness of 100 nm and a silicon dioxide layer having a thickness of 50 nm were stacked was used. After the evaporation apparatus was vacuum-exhausted to be 0.01 Pascal (Pa) or less, a current gradually flew into each material supply source to perform heating, and when the temperature reached a setting temperature, a shutter provided between the substrate and the material supply source was opened while rotating the substrate, thereby starting deposition. Note that the substrate temperature gradually rose from 80° C. to 160° C. The state of the deposition was confirmed, and when a film of a desired film thickness (200 μm) was formed, the shutter was closed to end the deposition. In this way, the columnar crystals containing cesium iodide as a main component were formed on the substrate. The main component refers to a component that constitutes equal to or more than 50% of the components contained in the columnar crystal, preferably equal to or more than 80%, and even more preferably equal to or more than 90%.

After cooling the substrate and the material supply sources to room temperature, the deposition film was quickly brought into contact with ethyl silicate, and the deposition film was coated by the vapor-phase growth method. Four substrates deposited at the same time in the steps until then were formed. For one of these substrates, a fluorescent X-ray analysis apparatus was used to measure the concentration of thallium that was an activator agent, and the concentration is found to be 0.34 mol %.

Subsequently, after one of the above-described substrates with the deposition films was set in a spray coater, protection films were formed using a solution raw material obtained by containing 1 wt % of perhydropolysilazane in a dibutyl ether solvent under the condition that a discharge amount and a scanning speed were set to obtain a wet film thickness of 100 μm.

After that, the above-described protection films were dried in an environment in which the temperature was 25° C. and the humidity was 50%, and then thermal treatment was performed using a clean oven. As the condition of thermal treatment, heating was performed in air at 230° C. for 1 hour, and then natural cooling was performed in the clean oven.

The deposition surface of the deposition film of the thus created scintillator was brought into tight contact with a CMOS photodetector via an FOP, and irradiated with radiation complying with radiation quality RQA5 of the international standards from the substrate side to acquire an image, thereby obtaining the quantity of light emission. An irradiation dose was 4.8 uGy and the output value of the CMOS photodetector was obtained as the quantity of light emission.

Next, the substrate with the deposition film was detached from the CMOS photodetector to evaluate radiation durability.

The evaluation condition was that a tube voltage was 130 kV, an aluminum (Al) added filter had a thickness of 1 mm, and an irradiation dose rate was 0.1 Gy/min. After irradiation of 100 Gy, the deposition surface of the deposition film was brought again into tight contact with the CMOS photodetector to measure the quantity of light emission. The measurement condition was the same as that for the preceding measurement, that is, RQA5 and an irradiation dose of 4.8 μGy were used. As a result, the quantity of light emission lowered by 11%, as compared with that before evaluation of radiation durability.

Similarly, after radiation durability was additionally evaluated, and irradiation of 900 Gy was further performed, the quantity of light emission was measured. As a result, the quantity of light emission lowered by 27%, as compared with that before evaluation of radiation durability.

### Comparative Example 1

Comparative Example 1 is the same as Example 1 up to formation of a scintillator containing cesium iodide as a base material and thallium iodide as an activator agent and having a columnar crystal structure by using the vacuum evaporation apparatus. However, in Comparative Example 1, no protection films containing perhydropolysilazane are formed. Furthermore, thermal treatment that was performed in Example 1 is not performed. In this state, during evaluation of radiation durability (to be described later), deliquescence occurs. To cope with this, a parylene film was formed to have a thickness of 10 μm to prepare a sample of Comparative Example 1.

The deposition surface of the thus created deposition film was brought into tight contact with the CMOS photodetector via the FOP, and irradiated with radiation complying with radiation quality RQA5 of the international standards from the substrate side to acquire an image, thereby obtaining the quantity of light emission. An irradiation dose was 4.8 μGy and the output value of the CMOS photodetector was obtained as the quantity of light emission.

Next, the substrate with the deposition film was detached from the CMOS photodetector to evaluate radiation durability.

The condition was that a tube voltage was 130 kV, an Al added filter had a thickness of 1 mm, and an irradiation dose rate was 0.1 Gy/min, which was the same condition as in Example 1. After irradiation of 100 Gy, the deposition surface of the deposition film was brought again into tight contact with the CMOS photodetector to measure the quantity of light emission. The measurement condition was the same as that for the preceding measurement, that is, RQA5 and an irradiation dose of 4.8 μGy were used. As a result, the quantity of light emission lowered by 21%, as compared with that before evaluation of radiation durability. This value is about twice as high as a lowering rate of 11% in Example 1.

Similarly, after irradiation of 900 Gy was further performed as additional evaluation of radiation durability, the quantity of light emission was measured. As a result, the quantity of light emission lowered by 38%, as compared with that before evaluation of radiation durability. This value is higher than a lowering rate of 27% in Example 1.

### Example 2

Example 2 is different from Example 1 described above in terms of the condition of thermal treatment. As the condition of thermal treatment, heating was performed in air at 210° C. for 3 hours, and then natural cooling was performed in a clean oven.

The deposition surface of the deposition film of the thus created scintillator was brought into tight contact with a CMOS photodetector via an FOP, and radiation durability was evaluated, similar to Example 1 and Comparative Example 1. As a result, after irradiation of 100 Gy, the quantity of light emission lowered by 12%, as compared with that before evaluation of radiation durability. After irradiation of 900 Gy was further performed, the quantity of light emission lowered by 35%, as compared with that before evaluation of radiation durability.

In Example 2 as well, the lowering rate of the quantity of light mission is low, as compared with Comparative Example 1. Table 1 shows a list of the results of Example 1, Example 2, and Comparative Example 1 described above.

TABLE 1

| | | | | | Lowering Rate of | |
|---|---|---|---|---|---|---|
| | | | Thermal Treatment | | Quantity of Light | |
| | Tl | | Condition | | Emission | |
| | Concentration | Protection | Temperature | Time | After | After |
| | [mol %] | Layer | [° C.] | [Hour] | 100 Gy | 1,000 Gy |
| Example 1 | 0.34 | silica | 230 | 1 | 11% | 27% |
| Example 2 | 0.34 | silica | 210 | 3 | 12% | 35% |
| Comparative | 0.34 | parylene | — | — | 21% | 38% |
| Example 1 | | | | | | |

### Example 3

In Example 3, a substrate on which a deposition film in which the concentration of Tl as an activator agent was 0.25 mol % was formed was prepared. After one substrate with a deposition film was set in a spray coater, protection films were formed using a solution raw material obtained by containing 1 wt % of perhydropolysilazane in a dibutyl ether solvent under the condition that a discharge amount and a scanning speed were set to obtain a wet film thickness of 100 μm.

After that, the above-described protection films were dried in an environment in which the temperature was 25° C. and the humidity was 50%, and then thermal treatment was performed using a clean oven. As the condition of thermal treatment, heating was performed in air at 230° C. for 1 hour, and then natural cooling was performed in the clean oven. This condition of thermal treatment is common to Example 1.

The deposition surface of the thus created deposition film was brought into tight contact with the CMOS photodetector via the FOP, and radiation durability was evaluated, similar to the above-described examples and comparative example. As a result, after irradiation of 100 Gy, the quantity of light emission lowered by 10%, as compared with that before evaluation of radiation durability. After irradiation of 900 Gy was further performed, the quantity of light emission lowered by 28%, as compared with that before evaluation of radiation durability.

### Example 4

Example 4 is different from Example 3 in terms of the condition of thermal treatment. As the condition of thermal treatment, heating was performed in air at 230° C. for 0.5 hour, and then natural cooling was performed in a clean oven. The deposition surface of the thus created deposition film was brought into tight contact with a CMOS photodetector via an FOP, and radiation durability was evaluated, similar to the above-described examples and comparative example. As a result, after irradiation of 100 Gy, the quantity of light emission lowered by 11%, as compared with that before evaluation of radiation durability. After irradiation of 900 Gy was further performed, the quantity of light emission lowered by 34%, as compared with that before evaluation of radiation durability.

### Comparative Example 2

Unlike Examples 3 and 4, in Comparative Example 2, no protection films containing perhydropolysilazane are formed. Furthermore, no thermal treatment is performed. In this state, during evaluation of radiation durability (to be described later), deliquescence occurs. To cope with this, a parylene film was formed to have a thickness of 10 μm to prepare a sample of Comparative Example 2.

The deposition surface of the thus created deposition film was brought into tight contact with the CMOS photodetector via the FOP, and radiation durability was evaluated, similar to the above-described examples and comparative example. As a result, after irradiation of 100 Gy, the quantity of light emission lowered by 22%, as compared with that before evaluation of radiation durability. After irradiation of 900 Gy was further performed, the quantity of light emission lowered by 41%, as compared with that before evaluation of radiation durability.

Table 2 shows a list of the results of Example 3, Example 4, and Comparative Example 2 described above. It is apparent from Table 2 that the time as the condition of thermal treatment influences the lowering rate of the quantity of light emission. Although the difference in quantity of light emission is small after irradiation of 100 Gy, the lowering rate of the quantity of light emission is lower as the time of thermal treatment is longer after irradiation of 1,000 Gy.

TABLE 2

| | | | | | Lowering Rate of | |
|---|---|---|---|---|---|---|
| | | | Thermal Treatment | | Quantity of Light | |
| | Tl | | Condition | | Emission | |
| | Concentration | Protection | Temperature | Time | After | After |
| | [mol %] | Layer | [° C.] | [Hour] | 100 Gy | 1,000 Gy |
| Example 3 | 0.25 | silica | 230 | 1 | 10% | 28% |
| Example 4 | 0.25 | silica | 230 | 0.5 | 11% | 34% |
| Comparative | 0.25 | parylene | — | — | 22% | 41% |
| Example 2 | | | | | | |

### Example 5

In Example 5, a deposition film in which the concentration of Tl as an activator agent was 0.71 mol % was prepared. After one substrate with a deposition film was set in a spray coater, protection films were formed using a solution raw material obtained by containing 1 wt % of perhydropolysilazane in a dibutyl ether solvent under the condition that a discharge amount and a scanning speed were set to obtain a wet film thickness of 100 μm. After that, the above-described protection films were dried in an environment in which the temperature was 25° C. and the humidity was 50%, and then thermal treatment was performed using a clean oven. As the condition of thermal treatment, heating was performed in air at 250° C. for 1 hour, and then natural cooling was performed in the clean oven.

The deposition surface of the thus created deposition film was brought into tight contact with a CMOS photodetector via an FOP, and radiation durability was evaluated, similar to the above-described examples and comparative examples. As a result, after irradiation of 100 Gy, the quantity of light emission lowered by 18%, as compared with that before evaluation of radiation durability. After irradiation of 900 Gy was further performed, the quantity of light emission lowered by 30%, as compared with that before evaluation of radiation durability.

### Example 6

Example 6 is different from Example 5 in terms of the condition of thermal treatment. As the condition of thermal treatment, heating was performed in air at 200° C. for 1 hour, and then natural cooling was performed in a clean oven. The deposition surface of the thus created deposition film was brought into tight contact with a CMOS photodetector via an FOP, and radiation durability was evaluated, similar to the above-described examples and comparative examples. As a result, after irradiation of 100 Gy, the quantity of light emission lowered by 22%, as compared with that before evaluation of radiation durability. After irradiation of 900 Gy was further performed, the quantity of light emission lowered by 35%, as compared with that before evaluation of radiation durability.

### Comparative Example 3

Unlike Examples 5 and 6, in Comparative Example 3, no protection films containing perhydropolysilazane are formed. Furthermore, no thermal treatment is performed. In this state, during evaluation of radiation durability (to be described later), deliquescence occurs. To cope with this, a parylene film was formed to have a thickness of 10 μm to prepare a sample of Comparative Example 3. The deposition surface of the thus created deposition film was brought into tight contact with the CMOS photodetector via the FOP, and radiation durability was evaluated, similar to the above-described examples and comparative examples.

As a result, after irradiation of 100 Gy, the quantity of light emission lowered by 29%, as compared with that before evaluation of radiation durability. After irradiation of 900 Gy was further performed, the quantity of light emission lowered by 45%, as compared with that before evaluation of radiation durability. Table 3 shows a list of the results of Example 5, Example 6, and Comparative Example 3 described above. It is apparent from Table 3 that the temperature as the condition of thermal treatment influences the lowering rate of the quantity of light emission. Although the difference in lowering rate is small after irradiation of 100 Gy, the lowering rate of the quantity of light emission is lower as the temperature of thermal treatment is higher after irradiation of 1,000 Gy.

TABLE 3

| | | | | | Lowering Rate of | |
|---|---|---|---|---|---|---|
| | | | Thermal Treatment | | Quantity of Light | |
| | Tl | | Condition | | Emission | |
| | Concentration | Protection | Temperature | Time | After | After |
| | [mol %] | Layer | [° C.] | [Hour] | 100 Gy | 1,000 Gy |
| Example 5 | 0.71 | silica | 250 | 1 | 18% | 30% |
| Example 6 | 0.71 | silica | 200 | 1 | 22% | 35% |
| Comparative | 0.71 | parylene | — | — | 29% | 45% |
| Example 3 | | | | | | |

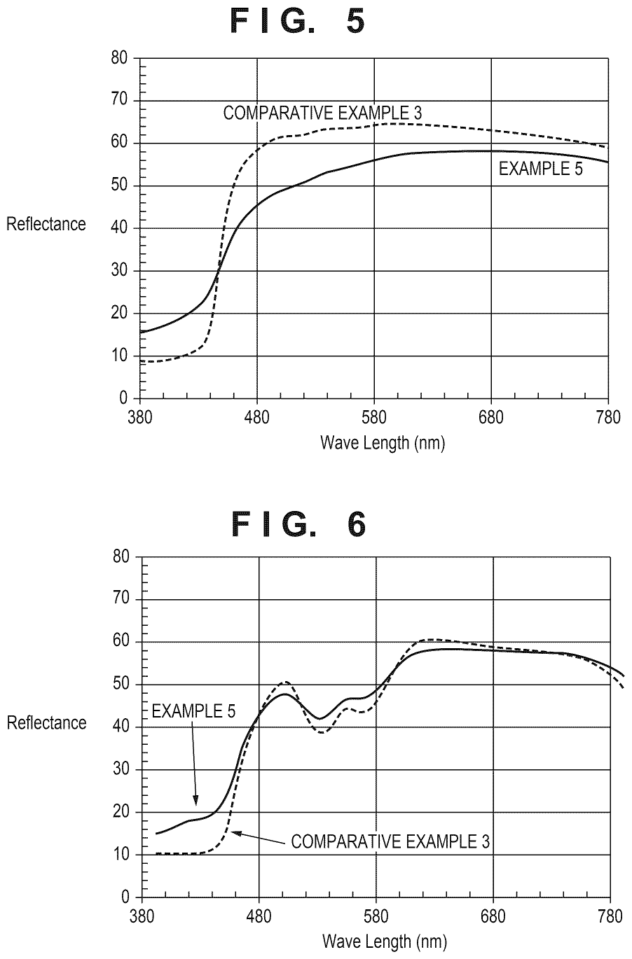

With respect to the samples in Example 5 and Comparative Example 3, the reflectance is also measured before evaluation of radiation durability and after irradiation of 1,000 Gy as accumulation. FIG. 5 shows the measurement result of the reflectance before evaluation of radiation durability. FIG. 6 shows the measurement result of the reflectance after irradiation of 1,000 Gy as accumulation. In the graph shown in FIG. 5, the abscissa represents a wavelength, and the ordinate represents the reflectance. The sample in Example 5 has a high reflectance in a wavelength range of about 450 nm or less and has a low reflectance in a wavelength range of 450 nm or more, as compared with Comparative Example 3.

The graph shown in FIG. 6 shows that even after irradiation of 1,000 Gy as accumulation, the sample in Example 5 tends to have a high reflectance within a range of about 450 nm or less, as compared with Comparative Example 3. Furthermore, the difference between Example 5 and Comparative Example 3 is small within a range of 450 nm or more. In particular, the reflectance largely lowers around a wavelength of 520 nm and a wavelength of 560 nm in Comparative Example 3 but the lowering is reduced in Example 5. This corresponds to suppression of the lowering rate of the quantity of light emission, which has been described above. Thus, in this example as well, radiation durability is improved.

### Summary of Examples

With respect to the scintillator described in each of Examples 1 to 6, the luminance of the scintillator after irradiation with radiation of 1,000 Gy by heat treatment lowered by 35% or less from the luminance of the scintillator before radiation irradiation. In the condition of thermal treatment in each of Examples 1 to 6, the temperature was 200° C. or higher. In each of Examples 1, 3, and 5, the luminance lowered by 30% or less. The temperature of thermal treatment in each of Examples 1, 3, and 5 was 230° C. or higher and the thermal treatment time was 1 hour or more. To the contrary, in each Comparative Example, the luminance lowered by 38% to 45%. As described above, when the temperature of thermal treatment was 200° C. or higher, the lowering rate of the luminance could be 35% or less. When the temperature of thermal treatment was 230° C. or higher and the thermal treatment time was 1 hour or more, the lowering rate of the luminance could be suppressed to 30% or less.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-001500, filed Jan. 9, 2024, which is hereby incorporated by reference herein in its entirety.

What is claimed is:

1. A scintillator comprising:
a plurality of columnar crystals arranged on a substrate and each configured to convert radiation into light; and
protection films configured to cover surfaces of the plurality of columnar crystals,
wherein the plurality of columnar crystals contain an activator agent,
the protection films contain silica, and
in a case that the scintillator is irradiated with radiation of 1,000 Gray (Gy), a quantity of light emission lowers by not more than 35%, as compared with a quantity of light emission before radiation irradiation.

2. The scintillator according to claim 1, wherein there are gaps between the protection films that cover the plurality of columnar crystals.

3. The scintillator according to claim 1, wherein the plurality of columnar crystals contain cesium iodide as a main component.

4. The scintillator according to claim 1, wherein in the case that scintillator is irradiated with radiation of 1,000 Gy, the quantity of light emission lowers by not more than 30%, as compared with the quantity of light emission before radiation irradiation.

5. The scintillator according to claim 1, wherein the activator agent is thallium, and a concentration of the activator agent is not lower than 0.25 mol %.

6. A scintillator comprising:
a plurality of columnar crystals arranged on a substrate and each configured to convert radiation into light; and
protection films configured to cover surfaces of the plurality of columnar crystals,
wherein the plurality of columnar crystals contain an activator agent,
the protection films contain silica, and
the scintillator has been exposed to thermal treatment.

7. The scintillator according to claim 6, wherein there are gaps between the protection films that cover the plurality of columnar crystals.

8. The scintillator according to claim 6, wherein the plurality of columnar crystals contain cesium iodide as a main component.

9. A radiation detector comprising:
the scintillator according to claim 1; and
a photoelectric conversion element configured to convert light from the scintillator into an electric charge.

10. A radiation imaging system comprising:
the radiation detector according to claim 9; and
a signal processing unit configured to process a signal from the radiation detector.

11. A method of manufacturing a scintillator, comprising:
forming a plurality of columnar crystals containing an activator agent on a substrate;
forming protection films containing silica on surfaces of the plurality of columnar crystals; and
performing thermal treatment at not lower than 200° C. after the formation of the protection films.

12. The method according to claim 11, wherein gaps are formed between the plurality of columnar crystals in a state in which the protection films are formed.

13. The method according to claim 11, wherein the plurality of columnar crystals contain cesium iodide as a main component.

14. The method according to claim 11, further comprising forming a film that planarizes the surfaces of the plurality of columnar crystals,
wherein the protection films are formed after the forming the film.

15. The method according to claim 11, wherein a concentration of a silica conversion material contained in a liquid material used to form the protection films is not less than 0.5 wt % and is not more than 2 wt %.

16. The method according to claim 11, wherein a silica conversion material contained in a liquid material used to form the protection films contains a polysilazane-based inorganic polymer.

17. The method according to claim 11, wherein a temperature of the thermal treatment is not lower than 230° C. and a time of the thermal treatment is not less than 1 hour.
